(19) United States
(12) Patent Application Publication
(10) Pub. No.: US 2009/0081109 A1
(43) Pub. Date: Mar. 26, 2009

(54) GaN CRYSTAL SHEET

(75) Inventor: Moshe Einav, Kfar Uriyah (IL)

Correspondence Address: MERCHANT & GOULD PC, P.O. BOX 2903, MINNEAPOLIS, MN, 55402-0903, US

(73) Assignee: Mosaic Crystals Ltd., Herzeliya Pituach (IL)

(21) Appl. No.: 12/092,935

(22) PCT Filed: Nov. 15, 2006
(86) PCT No.: PCT/IL06/01319

§ 371 Date: Oct. 1, 2008

Related U.S. Application Data
(60) Provisional application No. 60/737,786, filed on Nov. 17, 2005.

(51) Int. Cl. C01B 21/06; H01L 21/205

(52) U.S. Cl. 423/409; 438/508; 257/E21.108

(57) ABSTRACT

A method forms a gallium nitride crystal sheet. According to the method a metal melt, including gallium, is brought to a vacuum of 0.01 Pa or lower and is heated to a growth temperature of between approximately 860° C. and approximately 870° C. A nitrogen plasma is applied to the surface of the melt at a sub-atmospheric working pressure, until a gallium nitride crystal sheet is formed on top. Preferably, the growth temperature is of 863° C., and the working pressure is within the range of 0.05 Pa and 2.5 Pa. Application of the plasma includes introducing nitrogen gas to the metal melt at the working pressure, igniting the gas into plasma, directing the plasma to the surface of the metal melt, until gallium nitride crystals crystallize thereon, and maintaining the working pressure and the directed plasma until a gallium nitride crystal sheet is formed.

### FIELD OF THE DISCLOSED TECHNIQUE

The disclosed technique relates to gallium nitride crystal growth in general, and to methods and apparatus for forming gallium nitride crystal sheets, in particular.

### BACKGROUND OF THE DISCLOSED TECHNIQUE

Group-III metals of the periodic table (i.e., aluminum, gallium and indium) can form nitrides, i.e., aluminum nitride (AlN), gallium nitride (GaN) and indium nitride (InN). Group-III metal nitrides are semiconductors having various energy gaps (between two adjacent allowable bands), e.g., a narrow gap of 0.7 eV for InN, an intermediate gap of 3.4 eV for GaN, and a wide gap of 6.2 eV for AlN. Solid group-III metal nitrides have an ordered crystalline structure, giving them advantageous chemical and physical properties, such that electronic devices made from group-III metal nitrides can operate at conditions of high temperature, high power and high frequency. Furthermore, group-III metal nitrides are considered relatively chemically inert.

Electronic devices made from group-III metal nitrides may emit or absorb electromagnetic radiation having wavelengths ranging from the UV region to the IR region of the spectrum, which is particularly relevant for constructing light emitting diodes (LED), solid-state lights and the like. Other examples of applications of group-III metal nitride crystals are solid-state full color displays, optical storage devices, signal amplification devices, photovoltaic cells, under-water communication devices, space communication devices and the like. Furthermore, group-III metal nitrides may be used for other devices exhibiting solid state physical effects such as high semi-conducting electron mobility and saturation, opto-electricity, photo-luminescence, electro-luminescence, electron-emission, piezo-electricity, piezo-optics, diluted magnetism and the like.

To be used in various technological applications, the group-III metal nitride crystals may be in the form of a free-standing wafer or a thin film, attached to an arbitrary platform of conducting, semi-conducting, or dielectric nature. For other uses, group-III metal nitrides may be in the form of a free-standing bulk crystal. For industrial applications, group-III metal nitride crystals of large size (i.e., substantially 25 mm or larger) are required. However, crystals of large size, having a low defect density, are difficult to manufacture.

Group-III metal nitride crystals are not found naturally and are artificially produced as thin films on a crystalline substrate, by methods known in the art. Among the group-III metal nitrides, gallium nitride can be produced using hetero-epitaxy, wherein the substrate used as a hetero-epitaxial template can be, for example, a single-crystalline wafer of sapphire (Al₂O₃), on which a layer of GaN is deposited. Alternatively, a silicon carbide (SiC) wafer may be used as a substrate. However, due to the difference in lattice parameters between the substrate and the GaN layer, various crystal defects may appear in the GaN crystal.

Other known methods for growing group-III metal nitride crystals use a metallic melt, typically of the group-III metal. Nitrogen is supplied to the melt and chemically reacts with the group-III metal in the melt, thereby enabling crystal growth. Such methods are often expensive, and the crystal dimensions achieved, as well as the quantity of crystals produced, are typically small for industrial applications. Group-III metal nitride crystals, manufactured according to methods known in the art usually have crystal defects therein, such as dislocations, misorientations, vacancies, interstitial atoms, impurities, grain boundaries, and the like. In particular, none of the above mentioned methods are used to produce GaN crystal sheets of large dimensions, having a low defect density of less than 103 defects per centimeter squared.

PCT Publication WO 98/19964, to Angus et al., entitled “Method for the Synthesis of Group III Nitride Crystals”, is directed to a method for producing group-III nitride crystals from a liquid. The method is directed, in particular, to producing gallium nitride crystals. In one example, liquid gallium is held in a boron nitride crucible. The pressure inside the reaction chamber is reduced and the liquid is then heated to promote the desorption of trapped gas. An argon beam plasma and a hydrogen plasma are then used to remove impurities from the surface of the liquid gallium. An active nitrogen plasma is then used and the crucible is heated slowly, while pressure inside the crucible is maintained. Once the final temperature of 700° C. is attained, the nitrogen plasma beam is maintained on the surface of the liquid gallium for 12 hours. A supersaturation of the nitrogen is obtained and spontaneous crystallization occurs without cooling. Gallium nitride crystallizes on the surface of the liquid and forms a solid crust of GaN. A temperature gradient is imposed across the liquid surface such that one side of the liquid is held at a higher temperature than the other side. The solid GaN crust dissolves at the high temperature side and nitrogen is transported through the melt to the low temperature side, where the solid GaN recrystallizes. In this manner small crystals of solid GaN can be converted into larger crystals. In one example, a solid GaN polycrystalline dome, about 0.1 mm thick and having a surface area of 70 mm², was obtained. Scanning electron micrographs revealed randomly oriented crystallites of different structures (FIGS. 6 and 7). A transmission electron micrograph of a hexagonal platelet, found within the concave side of a GaN polycrystalline dome, revealed no dislocation defects, although other defects were present. In another example, instead of liquid gallium, an alloy containing 6.69 weight percent aluminum and 93.31 weight percent gallium was used as the starting metal. Upon crystallization, only polycrystalline aluminum nitride was obtained. No GaN was formed despite the presence of gallium in the melt.

Li, H., and Sunkara, M., “Self-Oriented Growth of Gallium Nitride Films on Amorphous Substrates,” Proceedings of the 4th Symposium on Non-Stoichiometric III-V Compounds (2002) is directed to a method for growing gallium nitride crystal films from a melt of gallium. Thin films of molten gallium are spread on an amorphous substrate. The gallium films are exposed to nitrogen plasma (i.e., nitrogen ions) and heated to a temperature of 900°-1,000° C. for 1-3 hours at a pressure of 100 mtorr. Gallium nitride crystals nucleate from the molten gallium, and self-orient with respect to each other due to the mobility of the melt. Separate platelets of GaN join together and form a larger GaN film. It is noted that the self-orientation of gallium nitride crystals described in the method of Li and Sunkara is not perfect, and that certain regions of the GaN film obtained contain joined crystals which are misorientated in a common plane with respect to one another. Such misorientations create gaps, or holes, between adjacent crystals, and render that region and layer of the crystal not useful for industrial applications. Other regions of the GaN film obtained contain platelets which are misoriented and are not in a common plane, whereby the platelets point in different directions with respect to one another. It is also noted that the GaN film obtained by the method of Li and Sunkara exhibits grain boundaries, which, between some platelets, is hardly seen due to complete joining of the platelets.

### SUMMARY OF THE PRESENT DISCLOSED TECHNIQUE

It is an object of the disclosed technique to provide a novel method and system for forming a gallium nitride crystal sheet. In accordance with the disclosed technique, there is thus provided a method for forming a gallium nitride crystal sheet, including providing a metal melt, which contains gallium. The method further includes bringing the pressure over said metal melt to 0.01 Pa or lower. The metal melt is heated to a growth temperature of between approximately 860° C. and approximately 870° C. The method also includes applying nitrogen plasma to the surface of the metal melt at a working pressure of between approximately 0.05 Pa and approximately 2.5 Pa, until a gallium nitride crystal sheet is formed on top of the metal melt. The gallium nitride crystal sheet is formed on top of a gallium nitride crystals layer (especially having a dendritic form), which crystallizes on said metal melt. Preferably, the growth temperature is of 863° C., and the working pressure is of 0.1 Pa. According an embodiment of the disclosed technique, the method further includes separating the gallium nitride crystal sheet from the metal melt, after applying the plasma. The method can also include post-processing of the gallium nitride crystal sheet. The method can further include growing epitaxial layers on said gallium nitride crystal sheet. According to another aspect of the disclosed technique there is provided a gallium nitride crystal sheet formed by the novel method.

### BRIEF DESCRIPTION OF THE DRAWINGS

The disclosed technique will be understood and appreciated more fully from the following detailed description taken in conjunction with the drawings in which:

FIG. 1 is a schematic illustration of a gallium nitride crystal sheet formation apparatus, constructed and operative in accordance with an embodiment of the disclosed technique;

FIG. 2 is a schematic illustration of a gallium nitride crystal sheet formation method, operative in accordance with another embodiment of the disclosed technique; and

FIG. 3 is a schematic illustration of the procedure of applying of FIG. 2, operative in accordance with a further embodiment of the disclosed technique.

### DETAILED DESCRIPTION OF THE EMBODIMENTS

The disclosed technique overcomes the disadvantages of the prior art by providing a method and apparatus for forming a gallium nitride crystal sheet of large dimensions having a low defect density, from a metal melt and a nitrogen plasma, by providing exact pressure and temperature growth conditions.

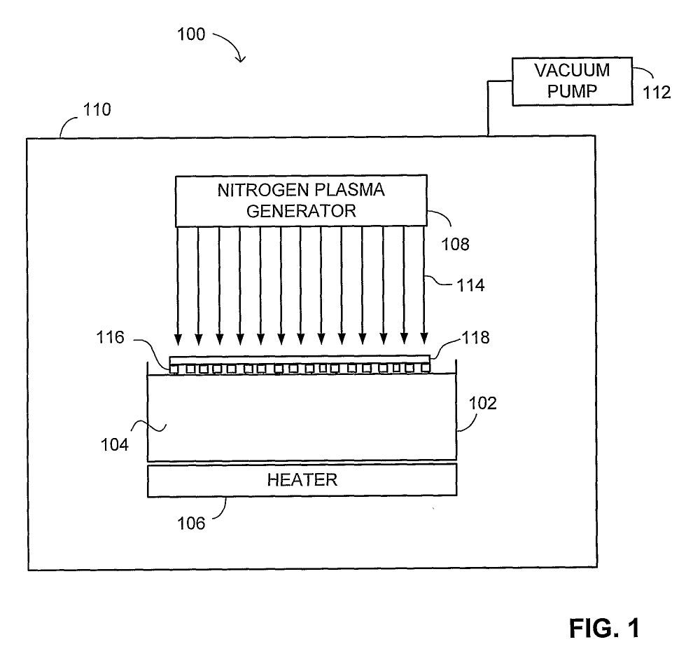

Reference is now made to FIG. 1, which is a schematic illustration of a side view of a gallium nitride crystal sheet formation apparatus, generally referenced 100, constructed and operative in accordance with an embodiment of the disclosed technique. Gallium nitride crystal sheet formation apparatus 100 includes a container 102, a heater 106, a nitrogen plasma generator 108, a vacuum chamber 110 and a vacuum pump 112. Container 102 contains a metal melt 104. Heater 106 is coupled with container 102. Vacuum pump 112 is coupled with vacuum chamber 110. Container 104 is placed inside vacuum chamber 110. Nitrogen plasma generator 108 is placed above the surface of metal melt 104, inside vacuum chamber 110, such that active nitrogen is directed (N or N⁺, as depicted by arrows 114) toward the surface of metal melt 104. It is noted that heater 106 can be placed either inside or outside of vacuum chamber 110.

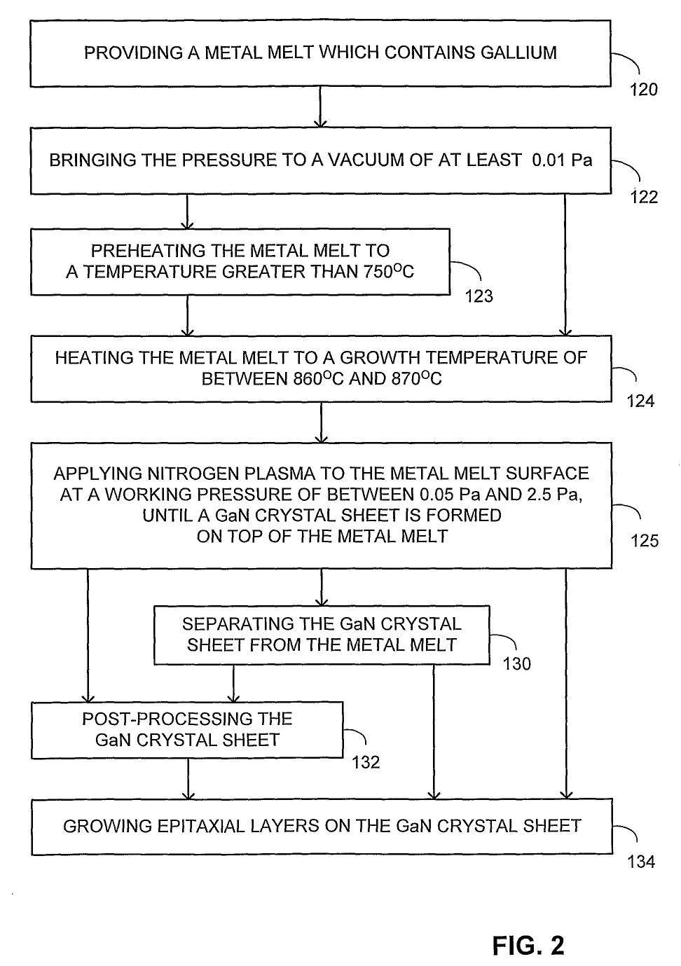

Reference is now made to FIG. 2, which is a schematic illustration of a gallium nitride crystal sheet formation method, operative in accordance with another embodiment of the disclosed technique. Since gallium nitride crystallizes in different crystalline forms (i.e., polymorphism) at different pressure and temperature conditions, the disclosed technique provides exact conditions for formation of a gallium nitride crystal sheet from a metal melt and a nitrogen plasma. The gallium nitride crystal sheet is formed on top of a net-like layer of dendritic gallium nitride crystals, which crystallize on the metal melt surface.

In procedure 120, a metal melt is provided, which contains gallium. The metal melt can be contained in a container. In procedure 122, the pressure over the metal melt is brought to a vacuum of at least 0.01 Pa (pascals). To achieve such a pressure, the metal melt can be placed, for example, in a vacuum chamber, or a pressure (vacuum) bell (i.e., a compartment open at its bottom) may be partially submerged in the metal melt, or in outer space. This vacuum is also referred to as “base pressure”. With reference to FIG. 1, container 102 is placed inside vacuum chamber 110. The pressure inside vacuum chamber 110 is brought, by pumping out the gas inside chamber 110 using vacuum pump 112, to a pressure of less than 0.01 Pa. A pressure bell or outer space location may be analogously applied instead of the vacuum chamber.

According to the disclosed technique, gallium nitride crystals of dendritic form are grown from the metal melt, by applying nitrogen plasma to the surface of the metal melt. The metal melt can be a pure gallium melt, or alternatively, a gallium-indium melt, which contains gallium as well as indium at a selected concentration. For example, the gallium-indium melt can contain 70 weight percent indium and 30 weight percent gallium. With reference to FIG. 1, container 102 contains metal melt 104. Metal melt 104 can be a pure gallium melt or a gallium-indium melt. In procedure 123, the metal melt is preheated to a temperature greater than approximately 750° C., and this temperature is maintained for a time period of approximately ten minutes. Preheating the metal melt is performed in order to dispose gases, solid native gallium oxide (GaO), or other contaminants which may be present. It is noted that procedure 123 is optional, and that the method depicted in FIG. 2 may proceed directly from procedure 122 to procedure 124, for example if removal of contaminants is not imperative. With reference to FIG. 1, heater 106 applies heat to container 102, thereby heating metal melt 104, to a temperature of approximately 750° C.

In procedure 124, the metal melt is heated to a growth temperature of between approximately 860° C.-870° C., which is suitable for GaN dendrite crystal growth. In particular, an effective growth temperature can be of 863° C. With reference to FIG. 1, heater 106 is located adjacent to the bottom of container 102 and applies heat thereto, thereby heating metal melt 104, until the temperature of metal melt reaches a growth temperature of between approximately 860° C.-870° C.

In procedure 125, nitrogen plasma is applied to the surface of the metal melt, at a sub-atmospheric pressure selected from the range of between approximately 0.05 Pa and approximately 2.5 Pa, until a GaN crystal sheet is formed on top of the metal melt. This sub-atmospheric pressure is also referred to as “working pressure”. Preferably, the working pressure is selected from the range of between approximately 0.05 Pa and approximately 0.2 Pa. In particular, a working pressure of about 0.1 Pa is most suitable.

It is noted, that the nitrogen plasma applied to the surface of metal melt 104, must include an appropriate amount of nitrogen ions. Obtaining an appropriate amount of nitrogen ions is achieved by the procedure of applying nitrogen plasma to the surface of metal melt 104 at working pressure. An appropriate amount of nitrogen ions can also be obtained by employing a faucet for controlling the flow of nitrogen ions applied to the surface of the metal melt, at a given working pressure, within or outside the sub-atmospheric pressure ranges mentioned above.

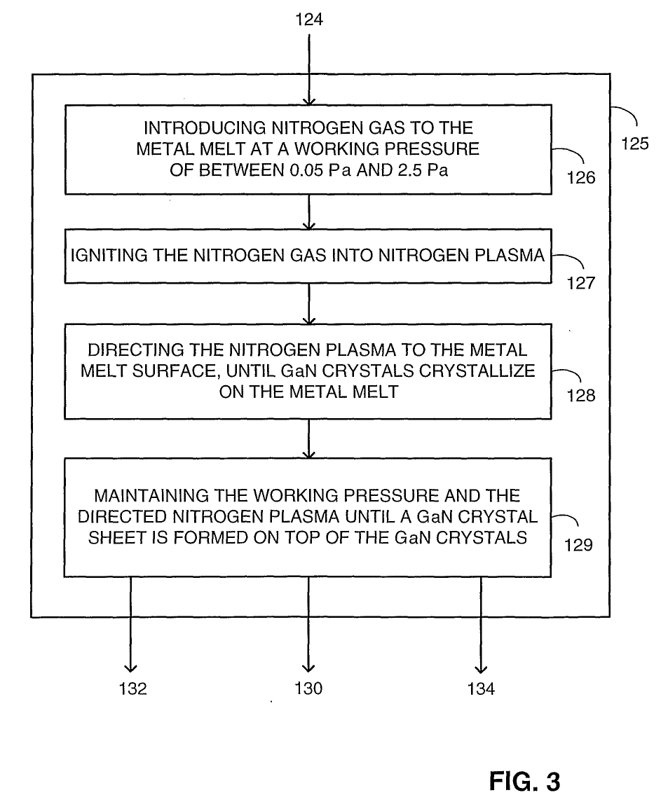

Reference is now made to FIG. 3, which is a schematic illustration of procedure 125 of FIG. 2, operative in accordance with a further embodiment of the disclosed technique, depicting the sub-procedures of procedure 125. In sub-procedure 126, pure, nitrogen gas is introduced to the metal melt, at a working pressure of between approximately 0.05 Pa and approximately 2.5 Pa (or 0.05-0.2 Pa). In particular, the working pressure can be of 0.1 Pa. In sub-procedure 127, the nitrogen gas is ignited and thus turned into nitrogen plasma. The pure nitrogen gas, which was introduced in sub-procedure 126, is ionized and is turning into nitrogen plasma (i.e., active nitrogen).

In sub-procedure 128, the nitrogen plasma is directed to the surface of the metal melt, until GaN crystals crystallize on the metal melt. It is noted that sub-procedure 127 and sub-procedure 128 may be performed in conjunction (i.e., as a single procedure, for example where a plasmatron ionizes the nitrogen and emits plasma of ionized nitrogen toward the surface of the metal melt. The active nitrogen reaching the surface of the metal melt reacts with or saturates the metal melt surface. As a result, dendrite GaN crystallizes on the surface of the metal melt. It is noted that certain plasma generators (i.e., plasmatrons) require a bias voltage. If such a plasma generator is used, a negative bias potential may be applied to the metal melt. The bias potential can be applied by direct current (DC), if a required potential is lower than approximately minus 1 Kilovolt. If a higher potential is required, negative alternating current (AC) may be used.

As the nitrogen plasma is directed to the metal melt, the active nitrogen reacts with the gallium in the metal melt, thereby causing crystallization of GaN crystals from the metal melt. The GaN crystals which crystallize from the metal melt posses substantially the same crystallographic orientation (e.g., 002 orientation, perpendicular to the metal melt surface). The GaN crystals may crystallize in different crystalline structures, for example some may crystallize as dendritic GaN, while others may crystallize as GaN platelets, or single crystal GaN bulky grains. The formation of the various GaN crystal structures depends mainly on the temperature of the metal melt. Under the given temperature and pressure conditions (i.e., 0.1 Pa and 863° C.), most of the GaN is likely to crystallize in the dendritic form on the surface of the metal melt. As the area covered by dendritic GaN crystals which crystallize on the metal melt increases, they form a net-like layer on the metal melt surface. With reference to FIG. 1, nitrogen plasma generator 108 is located above the surface of metal melt 104, such that it directs active nitrogen (N or N⁺, as depicted by arrows 114) toward the surface of metal melt 104. As a result, GaN crystals 116, typically having a dendritic form, crystallize from metal melt 104 and float to the surface thereof, such that they form a net-like layer on the metal melt surface.

In sub-procedure 129, the working pressure of the metal melt and the directed stream of nitrogen plasma are maintained until a GaN crystal sheet is formed on top of the GaN crystal net-like layer. Sub-procedure 129 can be performed for a predetermined amount of time, which can range from 1 minute to 5 minutes. In particular, this amount of time can be 3 minutes. The GaN crystal sheet forms in a wave-like expanding manner, starting from one particular location of the dendritic GaN crystal net-like layer, and spreading out there from. Sometimes there are several such particular locations, in which case the GaN crystal sheet spreads outwardly from all these particular locations to eventually meet and unite into one sheet. In this case, the GaN crystal sheet is constructed of two dimensional grains, each grain having a radius of a few millimeters. The grains have a typical lateral orientation (i.e., along the x and y axes, if taken in a Cartesian reference frame), and their perpendicular orientation (i.e., normal to the melt surface, along the z axis) remains constant (002). Although the GaN dendrite crystals, which crystallized on the metal melt in sub-procedure 128, may have different lateral crystalline orientations, the formed GaN crystal sheet (formed on the GaN dendrite crystals), or the grains of which the sheet is constructed, are not affected by these crystalline orientations and possess a uniform structure of an oriented single-crystal GaN sheet. Furthermore, although the GaN crystal net-like layer on the metal melt surface may inhibit holes or gaps, the GaN crystal sheet is formed over such holes or gaps and “bridges” them by covering the entire area in which the GaN crystals are present. The formed GaN crystal sheet typically contains a low crystal defect density of less than 10³ defects per centimeter squared. With reference to FIG. 1, as the working pressure and the directed nitrogen plasma are maintained, a GaN crystal sheet 118 is formed on top of GaN crystals 116. If the GaN crystal sheet is formed on the surface of the metal melt, which is contained in a container, the area size of the formed GaN crystal sheet is determined by, or confined to, the surface size of the container. Thus, if a container of large surface size is used, a GaN crystal sheet of the same size can be formed. The portion of the metal melt surface covered by the GaN crystal sheet depends on the period of time, during which the working pressure and the directed nitrogen plasma were maintained in sub-procedure 129. As this period of time is prolonged, the area of the GaN crystal sheet increases. It is noted that the thickness of the formed GaN crystal sheet is between approximately 0.2 μm (micrometer) and 0.3 μm.

Reference is further made to FIG. 2. In procedure 130, the GaN crystal sheet is separated from the metal melt, and can be used. According to one embodiment of the disclosed technique, separating the GaN crystal sheet from the metal melt can be performed by lifting the GaN crystal sheet out of the metal melt, for example by using a net or a lift. It is noted that since the GaN crystal sheet is formed on top of the GaN crystal net-like layer, the GaN sheet is attached to the net-like layer. Therefore, the sheet and the net-like layer are separated (i.e., removed) from the metal melt together. With reference to FIG. 1, a net (not shown) can be placed inside metal melt 104, adjacent and substantially parallel to the surface thereof. After GaN crystal sheet 118 is formed on metal melt 104, the net can be lifted out of metal melt 104. As the net exits metal melt 104, GaN crystal sheet 118 and GaN crystals 116 (being attached to each other) are both lifted by the net and are thereby separated from metal melt 104.

According to another embodiment of the disclosed technique, separating of the GaN crystal sheet from the metal melt can be performed by pulling the GaN crystal sheet out of the metal melt, for example by using a tweezers. With reference to FIG. 1, a tweezers (not shown) can be placed adjacent to the edges of container 102. After GaN crystal sheet 118 is formed on metal melt 104, the tweezers can be moved so as to grasp GaN crystal sheet 118 and pull it out of metal melt 104.

According to a further embodiment, the metal melt can be drained from the container, leaving only the GaN crystal sheet in the container. The sides of the container may be equipped with protruding elements, such that they are located beneath the metal melt surface. The container is equipped with a drainage outlet, for example at the bottom thereof, or with a pump for emptying the metal melt from the container. After the formation of the GaN crystal sheet, the metal melt is drained out of the container using the drainage outlet or the pump. The GaN crystal sheet remains in the container, either supported by the protruding elements, or on the bottom of the container. After draining the metal melt, the GaN crystal sheet can be used. It is noted that procedure 130 is optional, and the method depicted in FIG. 2 can proceed from procedure 125 directly to procedure 134, or from procedure 125 directly to procedure 132.

In procedure 132, the GaN crystal sheet is post-processed. Post-processing the GaN crystal sheet can include washing the GaN crystal sheet with an acid, for removing excess metal from the GaN crystal sheet, bonding the GaN crystal sheet to a substrate, sintering the GaN crystal sheet to a substrate, growing epitaxial layers on the GaN crystal sheet, doping the GaN crystal sheet, metallizing the GaN crystal sheet, sectioning the GaN crystal sheet, or performing micro-fabrication processes on the GaN crystal sheet (e.g., lithography, etching and deposition). It is noted that procedure 132 is optional, and the method depicted in FIG. 2 can proceed from procedure 130 directly to procedure 134, or from procedure 125 directly to procedure 134. In case procedure 130 is not performed, post processing can be performed as the GaN crystal sheet remains on the metal melt surface. In procedure 134, epitaxial crystal layers are grown on top of the GaN crystal sheet. For example, GaN films can be grown by homo-epitaxy crystal growth methods, as known in the art. After epitaxial layers are grown on top of the GaN crystal sheet, it can be removed from the container, and used. It is noted that procedure 134 is optional, and the method depicted in FIG. 2 can terminate after procedure 125.

It will be appreciated by persons skilled in the art that the disclosed technique is not limited to what has been particularly shown and described hereinabove. Rather the scope of the disclosed technique is defined only by the claims, which follow.

1. Method for forming a gallium nitride crystal sheet, comprising the procedures of:
providing a metal melt, said metal melt comprising gallium;
bringing the pressure over said metal melt to 0.01 Pa or lower;
heating said metal melt to a growth temperature of between approximately 860° C. and approximately 870° C.; and
applying nitrogen plasma to the surface of said metal melt at a sub-atmospheric working pressure until a gallium nitride crystal sheet is formed on top of said metal melt.

2. The method according to claim 1, wherein said procedure of applying comprises the sub-procedures of:
introducing nitrogen gas to said metal melt, at said sub-atmospheric working pressure;
igniting said nitrogen gas into nitrogen plasma;
directing said nitrogen plasma to the surface of said metal melt, until gallium nitride crystals crystallize on said metal melt; and
maintaining said working pressure and said directed nitrogen plasma until a gallium nitride crystal sheet is formed on top of said gallium nitride crystals.

3. The method according to claim 1, wherein said metal melt comprises a gallium melt.

4. The method according to claim 1, wherein said metal melt comprises a gallium-indium melt.

5. The method according to claim 1, wherein said working pressure is within the range of between approximately 0.05 Pa and approximately 2.5 Pa.

6. The method according to claim 5, wherein said working pressure is within the range of between approximately 0.05 Pa and approximately 0.2 Pa.

7. The method according to claim 6, wherein said working pressure is of approximately 0.1 Pa.

8. The method according to claim 1, wherein said growth temperature is of approximately 863° C.

9. The method according to claim 1, wherein said procedure of maintaining is performed for a predetermined amount of time is of between approximately 1 minute and approximately 5 minutes.

10. The method according to claim 9, wherein said predetermined amount of time is of approximately 3 minutes.

11. The method according to claim 1, further comprising the procedure of preheating said metal melt to a temperature greater than approximately 750° C., before said procedure of heating, for disposing of contaminants.

12. The method according to claim 11, wherein said contaminants comprise gases.

13. The method according to claim 11, wherein said contaminants comprise solid native gallium oxide.

14. The method according to claim 1, further comprising the procedure of separating said gallium nitride crystal sheet from said metal melt, after said procedure of applying.

15. The method according to claim 14, wherein said procedure of separating comprises at least one selected from the list consisting of:
lifting said gallium nitride crystal sheet out of said metal melt;
pulling said gallium nitride crystal sheet out of said metal melt; and
draining said metal melt, wherein said gallium nitride crystal sheet remains unattached from said metal melt.

16. The method according to claim 1, further comprising the procedure of post-processing said gallium nitride crystal sheet after said procedure of applying, said procedure of post-processing comprises at least one procedure selected from the list consisting of:
washing said gallium nitride crystal sheet with an acid, for removing excess metal from said gallium nitride crystal sheet;
bonding said gallium nitride crystal sheet to a substrate;
sintering said gallium nitride crystal sheet to a substrate;
growing epitaxial layers on said gallium nitride crystal sheet;
doping said gallium nitride crystal sheet;
metallizing said gallium nitride crystal sheet;
sectioning said gallium nitride crystal sheet; and
performing micro-fabrication processes on said gallium nitride crystal sheet.

17. The method according to claim 16, further comprising the procedure of separating said gallium nitride crystal sheet from said metal melt, after said procedure of applying and before said procedure of post-processing.

18. The method according to claim 1, further comprising the procedure of growing epitaxial layers on said gallium nitride crystal sheet after said procedure of applying.

19. The method according to claim 18, further comprising the procedure of separating said gallium nitride crystal sheet from said metal melt, after said procedure of applying and before said procedure of growing.

20. The method according to claim 18, further comprising the procedure of post-processing said gallium nitride crystal sheet from said metal melt, after said procedure of applying and before said procedure of growing.

21. A gallium nitride crystal sheet formed by a process comprising the procedures of:
providing a metal melt, said metal melt comprising gallium;
bringing the pressure over said metal melt to 0.01 Pa or lower;
heating said metal melt to a growth temperature of between approximately 860° C. and approximately 870° C.; and
applying nitrogen plasma to the surface of said metal melt at a sub-atmospheric working pressure until a gallium nitride crystal sheet is formed on top of said metal melt.
